(19) United States
(12) Patent Application Publication
(10) Pub. No.: US 2006/0189123 A1
(43) Pub. Date: Aug. 24, 2006

(54) Etchant and method of etching

(75) Inventors: Noriyuki Saitou, Fukuoka (JP); Takuji Yoshida, Kumamoto (JP); Kazunori Inoue, Tokyo (JP); Makoto Ishikawa, Fukuoka (JP); Yoshio Kamiharaguchi, Fukuoka (JP)

Correspondence Address: OBLON, SPIVAK, MCCLELLAND, MAIER & NEUSTADT, P.C., 1940 DUKE STREET, ALEXANDRIA, VA, 22314, US

(73) Assignees: ADVANCED DISPLAY INC., Kikuchi-gun (JP); MITSUBISHI CHEMICAL CORPORATION, Tokyo (JP)

(21) Appl. No.: 11/289,382

(22) Filed: Nov. 30, 2005

Related U.S. Application Data
(63) Continuation of application No. PCT/JP04/16913, filed on Nov. 9, 2004.

(30) Foreign Application Priority Data
Sep. 4, 2003 (JP) P. 2003-312852

(51) Int. Cl. H01L 21/4763; H01L 21/302

(52) U.S. Cl. 438/622; 438/745

(57) ABSTRACT

A fine wiring line profile with satisfactory precision is formed from a multilayer film containing a first layer made of an aluminum alloy and a second layer formed thereon made of a molybdenum-niobium alloy, by simultaneously etching the two layers constituting the multilayer film through only one etching operation while preventing the upper layer from forming overhangs. An etchant for etching a multilayer film containing an aluminum alloy layer formed over a substrate and a molybdenum-niobium alloy layer formed thereon having a niobium content of 2-19% by weight contains an aqueous solution of an acid mixture containing phosphoric acid, nitric acid, and an organic acid; and a method of etching is carried out with this etchant. The etchant preferably has a phosphoric acid concentration Nₚ of 50-75% by weight, a nitric acid concentration Nₙ of 2-15% by weight, and an acid ingredient concentration defined by Nₚ+(98/63)Nₙ of 55-85% by weight.

### TECHNICAL FIELD

The present invention relates to an etchant for use in patterning thin metal films by wet etching and to a method of etching with the same. More particularly, the invention relates to an etchant and an etching method for etching a multilayer film comprising an aluminum alloy layer and a molybdenum-niobium alloy layer.

### BACKGROUND ART

Recently, electrodes and gate wiring materials for use in semiconductor devices such as semiconductor elements and liquid-crystal display elements are increasingly required to have a higher degree of precision in microfabrication. In addition, it has been proposed to use metallic materials having a lower resistance. Examples of metallic materials having a low resistance include aluminum and aluminum alloys, and these materials are coming to be used increasingly.

Examples of techniques for processing a thin film of such a metal to form a pattern of a microstructure such as a wiring include wet etching techniques in which a photoresist pattern formed on the surface of a thin metal film by photolithography is used as a mask to conduct etching with a chemical to thereby pattern the metal film, and further include dry etching techniques such as ion etching and plasma etching.

Among those techniques, the wet etching techniques are economically advantageous over the dry etching techniques because the etching apparatus are inexpensive and relatively inexpensive chemicals are used. In addition, substrates having a large area can be evenly etched while attaining high productivity per unit time. Because of these, the wet etching techniques are frequently used as a process for producing a thin-film pattern.

During such processing for wiring formation, there are cases where aluminum and aluminum alloys develop hillocks (blisterlike projections generating on aluminum surfaces upon heat treatment) in a heat treatment step, e.g., substrate heating in film deposition in a process for semiconductor device production. The generation of hillocks makes it difficult to superpose an insulating film on the aluminum wiring. Namely, even when an insulating layer is formed on the aluminum wiring having hillocks on its surface, the hillocks remain penetrating through the insulating layer, resulting in insulation failures. The protruding parts of the hillocks cause short-circuiting when they come into contact with another conductive thin film layer.

There are also cases where when aluminum or an aluminum alloy is used as a wiring material and this wiring is directly contacted with ITO (indium oxide-tin oxide alloy) as a transparent electrode, then an altered layer is formed in that surface of the aluminum or aluminum alloy which is in contact with the ITO and, as a result, the contact part has increased contact resistance.

For preventing the hillock generation and altered-layer formation described above, various multilayer wirings have been proposed which comprise an aluminum or aluminum alloy layer and, superposed thereon, a layer of a different metal, e.g., a layer of a high-melting metal such as molybdenum or a molybdenum alloy or a chromium layer (see, for example, JP-A-9-127555, JP-A-10-256561, JP-A-2000-133635, JP-A-2001-77098, and JP-A-2001-311954).

### DISCLOSURE OF THE INVENTION

In the wet etching of multilayer films comprising an aluminum alloy layer and a molybdenum alloy layer superposed thereon as described above, some combinations of metals have resulted in exceedingly low production efficiency, for example, because of the necessity of successively etching the individual layers constituting the multilayer film with two different etchants. It is known that even when an etchant with which all layers constituting a multilayer film can be simultaneously etched is used, cell reactions occur due to contact with each of the layers of different metals, resulting in a different etching behavior, such as a higher etching rate than in the case of single-layer etching. (See, for example, SID CONFERENCE RECORD OF THE 1994 INTERNATIONAL DISPLAY RESEARCH CONFERENCE, p. 424.)

A difference in etching rate between layers of different metals may result in undercutting in the lower metal layer (the state in which the lower metal layer has been etched more quickly than the upper metal layer to leave overhangs of the upper metal layer) or side etching in the upper metal layer (the state in which the upper metal layer has been etched more quickly than the lower metal layer). There have been a problem in the parts which suffered undercutting, by this improper etching method, that covering with a gate insulating film (e.g., SiNₓ) in the overhang parts is insufficient because the multilayer film after the etching has a profile which is not tapered, resulting in insulation resistance failures, etc. There also is a problem that when the side etching of the upper metal layer occurs, the area of that part of the lower metal layer which is exposed is increased.

The invention has been achieved in view of those circumstances. An object of the invention is to provide an etchant and an etching method with which a multilayer film comprising an aluminum alloy layer having a low resistance and a molybdenum alloy layer formed thereon can be etched through one etching operation so as to form normally tapered side surfaces while preventing undercutting and side etching to thereby form a fine wiring line profile with satisfactory precision.

The etchant of the invention is an etchant for etching a multilayer film comprising an aluminum alloy layer formed over a substrate and a molybdenum-niobium alloy layer formed thereon having a niobium content of 2-19% by weight, and comprises an aqueous solution of an acid mixture comprising phosphoric acid, nitric acid, and an organic acid.

The etching method of the invention is a method of etching with an etchant a multilayer film comprising an aluminum alloy layer formed over a substrate and a molybdenum-niobium alloy layer formed thereon having a niobium content of 2-19% by weight, and the etchant is the etchant of the invention and that the ratio of the etching rate of the molybdenum-niobium alloy layer to the etching rate of the aluminum alloy layer [(etching rate of the molybdenum-niobium alloy layer)/(etching rate of the aluminum alloy layer)] is in the range of 0.7-1.3.

The present inventors made intensive investigations in order to overcome the problems described above. As a result, they have found that by using an etchant containing phosphoric acid, nitric acid, and an organic acid, a multilayer film such as that described above can be etched through one etching operation so as to form normally tapered side surfaces. The invention has been thus completed.

The investigations made by the inventors have revealed that the nitric acid in the etchant of the invention probably functions to lessen adhesion between the upper layer comprising a molybdenum-niobium alloy and the edges of the photoresist resin layer overlying the upper layer and thereby accelerate etchant penetration into the interface between these. Namely, the side etching rate of the molybdenum-niobium alloy layer in contact with the photoresist resin layer is heightened in a suitable degree, whereby the etching rate of the molybdenum-niobium alloy layer increases and the etching proceeds so as to form normally tapered side surfaces. Since the etching rate of the molybdenum-niobium alloy layer is higher than the etching rate of the aluminum alloy layer, the multilayer film can be etched with satisfactory precision so as to result in a normally tapered profile through one etching operation.

When the etchant of the invention has a phosphoric acid concentration Nₚ of 50-75% by weight, a nitric acid concentration Nₙ of 2-15% by weight, and an acid ingredient concentration defined by Nₚ+(98/63)Nₙ of 55-85% by weight, then it can have a further improved etching function.

It is preferred that in the multilayer film to be etched, the ratio of the thickness of the second layer (molybdenum-niobium alloy layer) t_{M} to the thickness of the first layer (aluminum alloy layer) t_{A}, t_{M}/t_{A}, be from 1/10 to 1/1.

In the invention, it is preferred that the etching rate of the molybdenum-niobium alloy layer be in the range of ±30% based on the etching rate of the aluminum alloy layer underlying that alloy layer.

### BRIEF DESCRIPTION OF THE DRAWINGS

FIG. 1A, FIG. 1B, and FIG. 1C are views showing examples of wiring line profiles formed by etching.

In the figures, reference numerals 1 and 3 each denotes a molybdenum-niobium alloy layer and 2 denotes an aluminum alloy layer.

### BEST MODE FOR CARRYING OUT THE INVENTION

Preferred embodiments of the etchant and etching method of the invention will be explained below in detail.

The etchant of the invention is for use in etching a multilayer film comprising an aluminum alloy layer and a molybdenum-niobium alloy layer formed thereon.

The etchant of the invention comprises an aqueous solution of an acid mixture comprising phosphoric acid, nitric acid, and an organic acid, and preferably has a phosphoric acid concentration Nₚ of 50-75% by weight, a nitric acid concentration Nₙ of 2-15% by weight, and an acid ingredient concentration defined by Nₚ+(98/63)Nₙ of 55-85% by weight.

In case where the phosphoric acid concentration therein is too high, the etching rate of the aluminum alloy layer becomes higher than the etching rate of the molybdenum-niobium alloy layer although the rate of etching of the multilayer film as a whole becomes higher. Undercutting hence proceeds and the molybdenum-niobium alloy layer protrudes to form overhangs. On the other hand, too low phosphoric acid contents are impractical because the etching rate is too low. Consequently, the phosphoric acid content is preferably regulated so as to be in the range shown above.

Nitric acid not only contributes as an oxidizing agent to oxidation reactions of the metals but also functions as an acid for dissolution. The nitric acid content in the etchant of the invention influences etching characteristics like the phosphoric acid content. Specifically, in case where the nitric acid content is too high, the etching rate of the aluminum alloy layer becomes higher than the etching rate of the molybdenum-niobium alloy layer although the rate of etching of the multilayer film as a whole becomes higher. Undercutting hence proceeds and the molybdenum-niobium alloy layer protrudes to form overhangs. There also is the possibility of damaging the photoresist resin layer. On the other hand, in case where the nitric acid content is too low, there is the possibility that the etching rate might be too low. Consequently, the nitric acid content is preferably regulated so as to be in the range shown above.

When the etchant of the invention contains acetic acid or an alkylsulfonic acid, the etching function thereof can be further improved.

The incorporation of acetic acid is effective in improving the affinity of the etchant for the photoresist resin layer, which is hydrophobic. Namely, the etchant can be made to readily penetrate into finely intricate areas in a fine wiring structure finely patterned with a photoresist resin mainly present on a substrate surface. As a result, even etching becomes possible.

The content of acetic acid in this case may be suitably determined according to the necessary etching area proportion, i.e., the ratio of the area of those metals present on the substrate which are to be etched (exposed metal surfaces) to the area masked with the photoresist resin layer, etc. The acetic acid content is generally 1-30% by weight, preferably 2-20% by weight.

Too low acetic acid contents result in an insufficient effect and may impair affinity for the photoresist resin layer formed over the substrate surface, making it impossible to conduct even etching. Conversely, even when the content thereof is too high, not only the photoresist resin layer may be damaged thereby, but also such high contents are economically disadvantageous because an improvement in effects which compensates for the increase in content cannot be attained.

Use of an alkylsulfonic acid in place of acetic acid has the following advantages. The odor characteristic of acetic acid can be eliminated, and affinity for the photoresist resin layer is improved. Furthermore, since the sulfonic acid is less apt to volatilize unlike acetic acid, it simultaneously produces an effect that the etchant can be inhibited from changing in composition or nature during the etching step and more stable etching can be conducted. The sulfonic acid may be used in combination with acetic acid. The sulfonic acid may be a salt, and examples of this sulfonic acid salt include potassium salts and ammonium salts.

The alkylsulfonic acid to be used in the invention preferably is methanesulfonic acid, ethanesulfonic acid, n-propanesulfonic acid, isopropanesulfonic acid, and n-butanesulfonic acid. Preferred of these are ethanesulfonic acid and methanesulfonic acid.

The content of the alkylsulfonic acid in the etchant of the invention may be suitably selected and determined according to the etching area proportion. The content thereof is generally 0.5-20% by weight, preferably 1-10% by weight.

As in the case of acetic acid described above, too low contents of the alkylsulfonic acid result in an insufficient effect and may impair affinity for the photoresist resin layer formed over the substrate surface, making it impossible to conduct even etching. Conversely, even when the content thereof is too high, not only the photoresist resin layer may be damaged thereby, but also such high contents are economically disadvantageous because an improvement in effects which compensates for the increase in content cannot be attained.

In the invention, the phosphoric acid concentration Nₚ is desirably 50-75% by weight, the nitric acid concentration Nₙ is desirably 2-15% by weight, and the acid ingredient concentration defined by Nₚ+(98/63)Nₙ is desirably 55-85% by weight, especially 60-80% by weight.

Furthermore, a surfactant or the like may be added to the etchant of the invention for the purpose of reducing the surface tension of the etchant or reducing the contact angle with the substrate surface to thereby improve the ability to wet the substrate surface and enable even etching.

Fine particles present in the etchant of the invention may come to inhibit even etching as pattern fineness becomes higher. It is therefore desirable to remove such fine particles beforehand to such a degree that the number of fine particles having a particle diameter of 0.5 μm or larger is reduce to 1,000 per mL or smaller. Fine particles present in the etchant can be removed by filtering the etchant through a precision filter. Although the filtration may be performed by a one-pass operation, it is preferred to conduct a circulation system from the standpoint of the efficiency of removing fine particles. As the precision filter can be used one having an opening diameter of 0.2 μm or smaller. As the material of the filter can be used high-density polyethylene, a so-called fluororesin material such as polytetrafluoroethylene, or the like.

The etchant of the invention is an etchant especially suitable for the etching of a multilayer film comprising a first layer made of an aluminum alloy and formed thereon a second layer made of a molybdenum-niobium alloy.

In this multilayer film, the ratio of the thickness of the second layer to that of the first layer (second-layer thickness/first-layer thickness) is not particularly limited. However, this layer thickness ratio is preferably from 1/10 to 1/1 because the effects of the invention described above are significant when the multilayer film having a layer thickness ratio within this range is etched.

Multilayer films comprising a first layer made of an aluminum alloy and formed thereon a second layer made of a molybdenum-niobium alloy are utilized, for example, as the wirings and gate electrodes formed on surfaces of substrates for liquid-crystal displays.

A suitable material for the first layer of the multilayer film described above is an alloy of aluminum and either neodymium or copper. In particular, an aluminum-copper alloy having a copper content of 0.05-3% by weight or an aluminum-neodymium alloy having a neodymium content of 1.5-15% by weight is suitable. The first layer may be any layer constituted mainly of an aluminum alloy, and the presence of impurities such as, e.g., other elements is not denied. Examples of such impurities include sulfur, magnesium, sodium, and potassium. It is, however, preferred that such impurities have been diminished to the lowest possible level. Specifically, the contents of these impurities each are preferably 200 ppm or lower. In particular, the contents of sodium and potassium each are preferably 20 ppm or lower because these two elements may exert considerable influence on properties of the semiconductor element.

A material suitable for the second layer is a molybdenum-niobium alloy having a niobium content of 2-19% by weight, especially 3-15% by weight.

This multilayer film is usually formed on an insulating substrate, e.g., a glass. Incidentally, a lower layer may have been formed between the substrate, e.g., a glass, and the first layer in order to heighten the adhesion of the multilayer film to the substrate. A suitable material for this lower layer is a molybdenum-niobium alloy, in particular, a molybdenum-niobium alloy having a niobium content of 2-19% by weight, especially 3-15% by weight.

The thickness tA of the first layer, which comprises an aluminum alloy, is preferably about 50-500 nm, and the thickness t_{M} of the second layer, which is an upper layer comprising a molybdenum-niobium alloy, is preferably about 10-100 nm. In particular, t_{M}/t_{A} is preferably 0.1-1, especially 0.2-0.8.

This multilayer film is produced by a known method.

The etching method, which uses the etchant of the invention, can be carried out using any of various machines and apparatus for wet etching.

For contacting the etchant with a multilayer film to be etched, use can be made of a method in which that surface of a substrate which has this multilayer film is sprayed with the etchant, for example, from the direction perpendicular to the surface (spraying method) or a method in which the substrate is immersed in the etchant (immersion method).

Especially in the spraying method, it is important to regulate the distance between the substrate to be etched and the spray nozzle and the spray pressure, while taking account of the liquid characteristics (especially viscosity) of the etchant, to determine the amount of the etchant to be supplied to the substrate surface and the force of the etchant striking on the substrate surface.

The distance between the substrate surface and the spray nozzle (shortest distance between the tip of the spray nozzle and the substrate surface) is preferably 50-1,000 mm. In case where this distance is shorter than 50 mm or exceeds 1,000 mm, it is difficult to regulate the spray pressure.

The spray pressure is preferably 0.01-0.3 MPa, more preferably 0.02-0.2 MPa, especially preferably 0.04-0.15 MPa. In the invention, the term “spray pressure” implies the pressure applied for supplying the etchant to the spray nozzle. By spraying the etchant over the substrate at this spray pressure, a moderate force is applied to the substrate surface and the surface can be evenly etched.

Etchant spray forms (spray nozzle shapes) are not particularly limited, and examples thereof include fan forms and cone forms. It is preferred that a necessary number of spray nozzles should be arranged along a substrate width direction and along a substrate travel direction and oscillated during spraying so that the etchant evenly strikes on the whole substrate surface. Simultaneously with the spraying of the etchant, the substrate itself may be reciprocated.

In the etching method of the invention, the temperature of the etchant may be suitably selected from general etching temperatures (20-60° C.). It is especially preferred to conduct the etching at 30-50° C. from the standpoint of a balance between etching rate improvement and etching control.

For monitoring the progress of etching in the etching method of the invention, any desired monitoring technique can be used. For example, use may be made of a technique in which the etching state of that part (substrate peripheral part) of a light-transmitting substrate (hereinafter sometimes referred to simply as “substrate”) which is not covered with a photoresist resin layer formed on the surface thereof or a part thereof located at the contour of the photoresist pattern is monitored by continuously measuring the changing light transmittance to thereby determine the amount of metals removed by etching. Thus, the progress of etching can be monitored.

Namely, light transmittance changes abruptly at the time when the dissolution of the thin metal layers terminates in that part (substrate peripheral part) of the substrate which is not covered with the photoresist resin layer formed on the surface thereof or in a part located at the contour of the photoresist pattern. This change can hence be utilized to detect an etching end point. In the invention, the time period required after etching initiation until the detection of that end point at which “transmittance changes abruptly” is referred to as just etching time. This end point may be determined, for example, by visually judging the point of time at which the metals in an area to be etched are wholly dissolved away by etching and the substrate is exposed. Alternatively, an actinometric (transmitted-light) automatic detector or the like may be used to determine, as an end point, the point of time at which the quantity of light transmitted through the substrate exceeds 0.1% of the quantity of light through the substrate in a completely transmitting state (the quantity of transmitted light when nothing is present on the substrate).

Overetching preferably is conducted after just etching in the etching method of the invention because metal residues can be present on the substrate surface at the time of end point detection.

It is preferred in the etching method of the invention that after the end point detection, overetching be successively conducted under the same etching conditions before the etching is completed. It is especially preferred that the time period of this overetching be regulated to from 25% to 300%, especially from 50% to 150%, of the just etching time.

When the overetching time is too short, there are cases where etching residues remain. When the overetching time is too long, there are cases where fine patterns such as multilayer film wirings are excessively etched due to side etching and come to have a reduced line width and this makes the device unable to work.

In general, when wet etching is conducted, ingredients in the etchant are consumed by the etching of the metals constituting the multilayer film or vaporize off. Furthermore, especially in wet etching, etchant ingredients adhere to the substrates and are taken out of the etching system together with the substrates. Since the amount of each ingredient in the etchant thus decreases, the etchant composition changes. In addition, the concentration of metal ions (main elements are aluminum and others which constitute the multilayer film) increases.

Especially in the method of wet etching by spraying, which is being frequently used from the standpoint of productivity, there is a strong tendency for the relative acid concentration to increase with diminution of volatile ingredients by vaporization.

It is preferred for more efficiently conducting etching by the etching method using the etchant of the invention that ingredients corresponding to those which have gone out of the etching system, such as the low boiling point ingredients which have vaporized off in the etching step and the ingredients contained in the etchant which has adhered to and been taken out by the substrate during the etching treatment, be additionally supplied to the etching system continuously or intermittently. Thus, stable etching can be conducted.

In this case, it is preferred in the etching method of the invention that etchant ingredients corresponding to those consumed by etching or taken out of the etching system should be additionally supplied to the etchant so as to result in a phosphoric acid content of 50-75% by weight, a nitric acid content of 2-15% by weight, and a value of the acid ingredient concentration (Nₚ+(98/63)Nₙ) of 55-85% by weight, before the etching is continuously conducted.

For replenishing etchant ingredients in the etching method of the invention, any desired technique may be used. Examples thereof include the following.

For example, a technique may be used in which an etchant replenisher composition, amount thereof, and replenishment timing are determined beforehand. Namely, the composition of low boiling point ingredients (e.g., acetic acid and water) which vaporize in an etching step can be specified when the etchant composition and etchant temperature are kept constant. This is because vapor-liquid equilibrium holds when the composition of the initial etchant (original etchant) and the temperature of the etchant are fixed. The amount of the etchant which vaporizes (vaporization rate) depends on the degree of evacuation of the etching system (amount of gases discharged from the etching system), etc. Consequently, changes in etchant composition after etching initiation can be determined beforehand by taking these factors into account and, based on this, a replenisher composition, replenisher amount to be added, and replenishment timing can be determined.

The composition and amount of ingredients which vaporize during an etching step can be calculated from a concentration change in the etchant per unit time period measured with an existing concentration analyzer, when the etching conditions (etchant composition, etchant temperature, etc.) are constant. Consequently, a replenisher composition, replenisher amount to be added, and replenishment timing may be determined from these values calculated.

Alternatively, use may be made of a method in which an existing concentration analyzing apparatus is used to continuously or intermittently monitor the composition of the etchant in an etching step and etchant ingredients are continuously or intermittently supplied to the etching system based on the results of the analysis.

Etchant ingredients are additionally supplied continuously or intermittently, while taking account of the thus-calculated amount of each ingredient to be added, so as to result in ingredient amounts within the ranges shown above. Thus, continuous etching may be conducted. The etchant ingredients to be additionally supplied may be added either separately or as a mixture thereof.

It is also noted that the amount of the etchant present in the etching system decreases with the progress of etching because part of the etchant adheres to the substrate which has been etched and is taken out of the etching system together with the substrate. When the etchant amount decreases considerably, there are cases where, in wet etching by spraying, for example, cavitation or the like occurs in the etchant feed pump to make it difficult to continuously conduct stable wet etching. Furthermore, such a reduced etchant amount may arouse a trouble that the etchant heater or the like disposed, for example, in the etchant tank is exposed on the liquid surface and, hence, the control of etchant temperature becomes insufficient. It is therefore preferred that an etchant (original etchant) be suitably added so that the etchant amount in the etching system is kept on a level within a certain range.

Specifically, this replenishment may be accomplished in the following manner. A weight change per substrate through etching is determined, or the concentration of acids brought into the rinsing step conducted subsequently to the etching step is determined. The number of substrates to be etched and the amount of the etchant to be taken out of the etching system are calculated beforehand from the weight change or the acid concentration. This amount may be taken as the amount of an etchant (original etchant) to be additionally supplied.

By thus regulating the concentration of each ingredient and concentration of metal ions in the etchant, the etchant can be used while being recycled. This method is hence advantageous also from the standpoint of profitability.

According to the etching method of the invention described above, a multilayer film comprising, for example, an aluminum alloy layer and a molybdenum-niobium alloy layer can be evenly etched stably with satisfactory precision through one etching operation to obtain the target wiring line profile having no overhangs.

It is preferred in the etching method of the invention that the ratio of the etching rate of the molybdenum-niobium alloy layer to the etching rate of the aluminum alloy layer [(etching rate of the molybdenum-niobium alloy layer)/(etching rate of the aluminum alloy layer)] be in the range of 0.7-1.3, especially 0.8-1.2.

In the invention, an optimal range of the composition of the etchant varies depending on the films to be etched. It is therefore desirable to change the composition of the etchant according to, e.g., the niobium content of the molybdenum-niobium alloy layer to be etched, so as to result in a value of that etching rate ratio in the range of 0.7-1.3, more preferably 0.8-1.2. A person skilled in the art can determine an optimal composition range without conducting undue experiments.

For example, for use in the etching of a molybdenum-niobium alloy layer having a niobium content of 5% by weight, which is shown in the Examples given below, the etchant preferably has a phosphoric acid concentration Nₚ of 50-75% by weight, a nitric acid concentration Nₙ of 2-15% by weight, an acid ingredient concentration defined by Nₚ+(98/63)Nₙ of 55-85% by weight, and an acetic acid concentration of 3-10% by weight. An alkylsulfonic acid may be used in place of the acetic acid in a concentration of 1.5-8% by weight.

### EXAMPLES

The invention will be explained below in more detail by reference to Examples and Reference Examples, but the invention should not be construed as being limited to the following Examples unless the invention departs from the spirit thereof.

### Examples 1 to 7 and Reference Examples 1 to 6

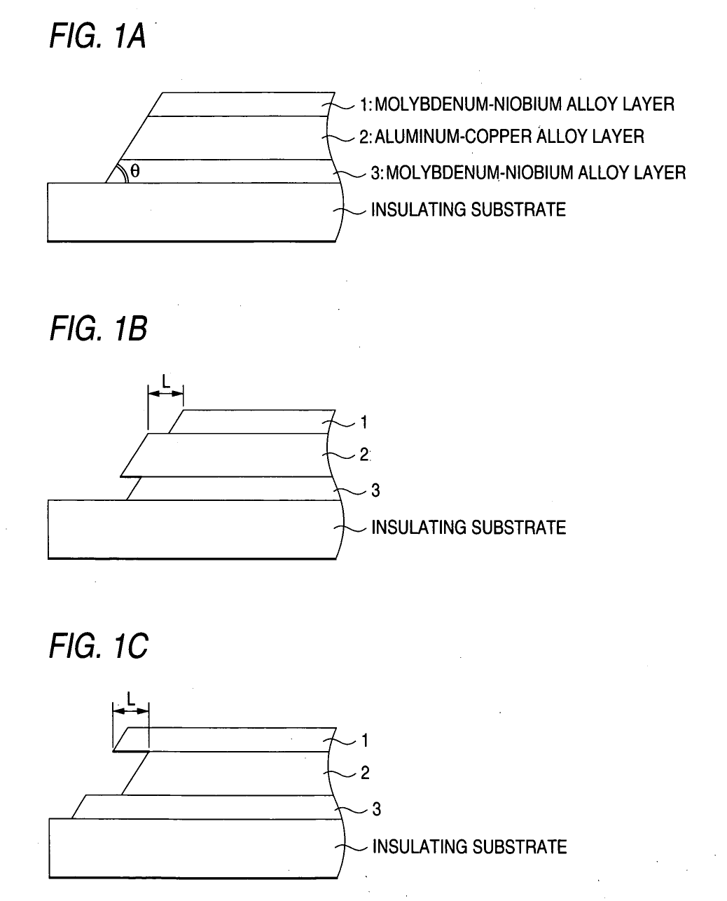

A molybdenum-niobium alloy layer (niobium content, 5% by weight) 3 having a thickness of 50 nm was deposited on a glass substrate by sputtering. On this layer was deposited AlCu (aluminum-copper alloy; copper content, 5% by weight) in a thickness of 300 nm as an aluminum alloy layer 2 by sputtering using argon gas. Thereafter, a molybdenum-niobium alloy layer 1 having the same composition as shown above and having a thickness of 50 nm was continuously deposited. Thus, an MoNb/AlCu/MoNb multilayer film was formed as shown in FIG. 1A, FIG. 1B, and FIG. 1C.

A positive photoresist resin layer (thickness, about 1.5 μm) was further formed thereon by spin coating, and this layer was treated by photolithography to form a fine wiring pattern. The line width of this resist pattern was about 5 μm.

This substrate was cut into pieces having a width of about 10 mm and a length of 50 mm, and these pieces were used as etching test samples.

On the other hand, a molybdenum-niobium alloy layer having the same thickness as shown above was formed as the only metal layer on a glass substrate, and a photoresist layer was formed in the same manner. Cut pieces of this coated substrate were used as etching test samples for a molybdenum-niobium alloy single-layer film.

Phosphoric acid (85% by weight aqueous solution), nitric acid (70% by weight aqueous solution), acetic acid (glacial acetic acid), and pure water were mixed together optionally together with methanesulfonic acid so as to result in the compositions shown in Table 1 to prepare etchants. Each etchant was filtered through a precision filter. In 200-mL beakers were respectively placed 200 g each of the etchants. The temperatures of these etchants were adjusted to 40° C. The etching test samples described above were immersed in the etchants and etched while moving the samples up and down and from side to side.

The time period from etching initiation to an end point was regarded as etching time. The end point was determined by visually determining the point of time at which those metals on the substrate which were located in an area to be etched were wholly dissolved away and the substrate was exposed (became transparent).

An etching rate was calculated from the etching time and the layer thickness.

The etching rate of a molybdenum-niobium alloy layer can be determined by dividing the thickness of this layer by the etching time of the single-layer film of the alloy.

The etching rate of the aluminum alloy layer in the multilayer film can be determined in the following manner. The etching time of the molybdenum-niobium alloy single-layer films is subtracted from the etching time of the whole multilayer film to thereby determine the etching time of the aluminum alloy layer alone. Subsequently, the thickness of the aluminum alloy layer is divided by this etching time to thereby determine the etching rate of the aluminum alloy layer alone.

The etching rate of each layer thus obtained and the etching rate ratio [(etching rate of the molybdenum-niobium alloy layer)/(etching rate of the aluminum alloy layer)] are shown in Table 1.

The surface states of the substrates after the etching were examined by the following methods, and the results are shown in Table 1.

[1] State of Resist

The state of the photoresist resin layer was examined (for swelling, cracking, etc.) with a laser microscope (VK-8500, manufactured by Keyence Corp.) and evaluated based on the following criteria.

◯=no change

X=defect such as swelling or cracking occurred

[2] Wiring Line Profile

A scanning electron microscope (SEM) or a focused ion beam (FIB) (FB-2000A and C-4100, manufactured by Hitachi Ltd.) was used to examine the state of overhangs (protrusion length L) shown in FIG. 1C and the state of residues around an electrode, and the profile was evaluated based on the following criteria.

State of Overhangs (Length):

X: L is 60 nm or longer

◯: L is shorter than 60 nm

Prior to the examination of wiring line profiles, the photoresist resin layer formed over the substrate surface was removed by dissolution with acetone. Other examples of wiring line profiles are shown in FIG. 1A and FIG. 1B. FIG. 1A is a most preferred profile example, and FIG. 1B shows a profile example in which a molybdenum-niobium alloy layer has been overetched.

TABLE 1

| | | | | | | | Acid | Etching rate [nm/min] | | | | | | |
|---|---|---|---|---|---|---|---|---|---|---|---|---|---|---|
| | | Etchant composition [wt %] | | | | | ingredient | Molybdenum- | | Aluminum | | Wiring line | | |
| | | phos- | | | | | concen- | niobium | Multi- | alloy | Etching | profile | | |
| | | phoric | Nitric | | Methane- | | tration | alloy | layer | layer in | rate | O.E. = 50% | | State |
| | | acid | acid | Acetic | sulfonic | | (Nₚ + | singlelayer | film | multilayer | ratio | Pro- | | of |
| | No. | (Nₚ) | (Nₙ) | acid | acid | Water | (98/63)Nₙ) | film | (whole) | film | [−] | file | Residue | resist |
| Example | 1 | 65 | 8 | 6.5 | — | 20.5 | 77.4 | 466 | 453 | 449 | 1.038 | ◯ | ◯ | ◯ |
| | 2 | 65 | 8 | 8.25 | — | 18.75 | 77.4 | 361 | 387 | 397 | 0.909 | ◯ | ◯ | ◯ |
| | 3 | 68.8 | 5 | 5 | — | 21.2 | 76.6 | 511 | 421 | 398 | 1.284 | ◯ | ◯ | ◯ |
| | 4 | 68.8 | 5 | 6.8 | — | 19.4 | 76.6 | 393 | 429 | 442 | 0.889 | ◯ | ◯ | ◯ |
| | 5 | 68.8 | 5 | 8.5 | — | 17.7 | 76.6 | 296 | 364 | 393 | 0.753 | ◯ | ◯ | ◯ |
| | 6 | 72.5 | 2 | 8.5 | — | 17 | 75.6 | 253 | 320 | 351 | 0.721 | ◯ | ◯ | ◯ |
| | 7 | 68.8 | 5 | — | 5 | 21.2 | 76.6 | 490 | 480 | 477 | 1.027 | ◯ | ◯ | ◯ |
| Compara- | 1 | 50 | 10 | 2.5 | — | 37.5 | 65.6 | 3429 | 198 | 151 | 22.709 | X | ◯ | ◯ |
| tive | 2 | 65 | 8 | 11.8 | — | 15.2 | 77.4 | 209 | 329 | 407 | 0.514 | X | ◯ | ◯ |
| Example | 3 | 68.8 | 5 | 11.8 | — | 14.4 | 76.6 | 168 | 312 | 436 | 0.385 | X | ◯ | ◯ |
| | 4 | 72.5 | 2 | 11.5 | — | 14 | 75.6 | 131 | 258 | 381 | 0.344 | X | ◯ | ◯ |
| | 5 | 68.8 | 5 | — | 1 | 25.2 | 76.6 | 1044 | 480 | 407 | 2.565 | X | ◯ | ◯ |
| | 6 | 68.8 | 5 | — | 8.5 | 17.7 | 76.6 | 245 | 369 | 444 | 0.552 | X | ◯ | ◯ |

The following are apparent from Table 1. Namely, in Reference Examples 1 and 5, the ratio of the etching rate of the molybdenum-niobium alloy layers to the etching rate of the aluminum-copper alloy as an interlayer was larger than 1.3, and the profiles after etching were FIG. 1B because of a large side etching amount of the molybdenum-niobium alloy layers.

In Reference Examples 2, 3, 4, and 6, the ratio of the etching rate of the molybdenum-niobium alloy layers to the etching rate of the aluminum-copper alloy as an interlayer was smaller than 0.7, and the profiles after etching were FIG. 1C due to the delayed etching of the molybdenum-niobium alloy layers. Because of these, the wiring line profiles in Reference Examples 1 to 6 each were judged to be X.

In contrast, in Examples 1 to 7, all the results of the evaluations including profile evaluation were satisfactory.

While the invention has been described in detail and with reference to specific embodiments thereof, it will be apparent to one skilled in the art that various changes and modifications can be made therein without departing from the spirit and scope thereof.

The contents of a Japanese patent application filed on Sep. 4, 2003 (Application No. 2003-312852) are herein incorporated by reference.

### INDUSTRIAL APPLICABILITY

According to the etchant and etching method of the invention, a multilayer film comprising an aluminum alloy layer and a molybdenum alloy layer formed thereon can be etched through only one etching operation so as to result in normally tapered side surfaces, whereby a fine wiring line profile with satisfactory precision can be formed.

Therefore, according to the invention, a wiring material comprising the low-resistance multilayer film having excellent electrical properties can be stably and evenly etched with satisfactory precision and a highly reliable wiring can be formed at low cost. Thus, highly reliable liquid-crystal displays and the like can be provided at low cost.

1. An etchant for etching a multilayer film comprising an aluminum alloy layer formed over a substrate and a molybdenum-niobium alloy layer formed thereon having a niobium content of 2-19% by weight,
comprising an aqueous solution of an acid mixture comprising phosphoric acid, nitric acid, and an organic acid.

2. The etchant as claimed in claim 1, characterized by having
a phosphoric acid concentration Nₚ of 50-75% by weight,
a nitric acid concentration Nₙ of 2-15% by weight, and
an acid ingredient concentration defined by Nₚ+(98/63)Nₙ of 55-85% by weight.

3. The etchant as claimed in claim 2, characterized in that the organic acid is acetic acid or an alkylsulfonic acid.

4. The etchant as claimed in claim 2, characterized in that the organic acid is acetic acid and the concentration thereof is 1-30% by weight.

5. The etchant as claimed in claim 2, characterized in that the organic acid is methanesulfonic acid, ethanesulfonic acid or both of them and the concentration thereof is 0.5-20% by weight.

6. A method of etching with an etchant a multilayer film comprising an aluminum alloy layer formed over a substrate and a molybdenum-niobium alloy layer formed thereon having a niobium content of 2-19% by weight, wherein
the etchant comprises an aqueous solution of an acid mixture comprising phosphoric acid, nitric acid, and an organic acid, and
the ratio of the etching rate of the molybdenum-niobium alloy layer to the etching rate of the aluminum alloy layer, (etching rate of the molybdenum-niobium alloy layer)/(etching rate of the aluminum alloy layer), is in the range of 0.7-1.3.

7. The method of etching as claimed in claim 6, characterized in that the multilayer film further has a lower layer interposed between the aluminum alloy layer and the substrate, the lower layer comprising a molybdenum-niobium alloy having a niobium content of 2-19% by weight.

8. The method of etching as claimed in claim 6, characterized in that the aluminum alloy is an aluminum-copper alloy having a copper content of 0.05-3% by weight or an aluminum-neodymium alloy having a neodymium content of 1.5-15% by weight.

9. The method of etching as claimed in claim 6, characterized in that the ratio of the thickness of the upper molybdenum-niobium alloy layer t_{M} to the thickness of the underlying aluminum alloy layer t_{A}, t_{M}/t_{A}, is from 0.1 to 1.

10. The method of etching as claimed in claim 6, characterized by having
a phosphoric acid concentration Np of 50-75% by weight,
a nitric acid concentration Nn of 2-15% by weight, and
an acid ingredient concentration defined by Nₚ+(98/63)Nₙ of 55-85% by weight.

11. The method of etching as claimed in claim 6, characterized in that the organic acid is acetic acid or an alkylsulfonic acid.

12. The method of etching as claimed in claim 6, characterized in that the organic acid is acetic acid and the concentration thereof is 1-30% by weight.

13. The method of etching as claimed in claim 6, characterized in that the organic acid is methanesulfonic acid, ethanesulfonic acid or both of them and the concentration thereof is 0.5-20% by weight.
